(19) United States
(12) Patent Application Publication
(10) Pub. No.: US 2026/0129758 A1
(43) Pub. Date: May 7, 2026

(54) CIRCUIT BOARD AND ELECTRONIC DEVICE INCLUDING THE SAME

(71) Applicant: Samsung Display Co., Ltd., Yongin-si (KR)

(72) Inventor: Sedae KI, Yongin-si (KR)

(73) Assignee: Samsung Display Co., Ltd., Yongin-si (KR)

(21) Appl. No.: 19/282,620

(22) Filed: Jul. 28, 2025

(30) Foreign Application Priority Data
Nov. 5, 2024 (KR) 10-2024-0154873

(51) Int. Cl. H05K 1/11; H04M 1/02

(52) U.S. Cl. CPC H05K 1/117; H04M 1/0266; H05K 2201/10189

(57) ABSTRACT

A circuit board may include: a base substrate; a connection pad on the base substrate, wherein an upper surface of the connection pad in a first direction includes an inclined surface and a concave portion, the concave portion being at a central portion of the upper surface in a second direction that crosses the first direction; and a connector on the connection pad, the connector including a connection pin that contacts the concave portion.

### CROSS-REFERENCE TO RELATED APPLICATION

This application claims priority under 35 USC § 119 to Korean Patent Application No. 10-2024-0154873, filed on Nov. 5, 2024, in the Korean Intellectual Property Office, the disclosure of which is herein incorporated by reference in its entirety.

### BACKGROUND

### 1. Field

Some embodiments of the present disclosure generally to a circuit board. More particularly, some embodiments of the present disclosure relates to a circuit board and an electronic device including the same.

### 2. Description of Related Art

With the development of information technology, the importance of a display device, which is a connection medium between a user and information, has been highlighted. For example, the use of display devices such as a liquid crystal display (LCD) device, an organic light emitting diode (OLED) display device, a plasma display panel (PDP) device, quantum dot display device or the like is increasing.

The display device may include a display panel including a pixel and a circuit board electrically connected to the display panel. The circuit board may include a base substrate and electronic elements arranged on the base substrate. For example, the electronic elements may include a voltage generator that generates a voltage applied to the pixel, a driving controller that controls driving of the display panel, a connector that electrically connects an external device and the circuit board, or the like. The connector may include a connection pin that contacts a connection pad formed on the base substrate. The connection pin may be bonded to the connection pad through a reflow process, and the connector may be mounted on the base substrate.

Information disclosed in this Background section has already been known to or derived by the inventors before or during the process of achieving the embodiments of the present application, or is technical information acquired in the process of achieving the embodiments. Therefore, it may contain information that does not form prior art that is already known to the public.

### SUMMARY

According to some embodiments of the present disclosure, a circuit board having reduced positional deviation of a connection pin formed on a connection pad may be provided.

According to some embodiments of the present disclosure, an electronic device including the circuit board may be provided.

According to some embodiments of the present disclosure, a circuit board may include: a base substrate; a connection pad on the base substrate, wherein an upper surface of the connection pad in a first direction includes an inclined surface and a concave portion, the concave portion being at a central portion of the upper surface in a second direction that crosses the first direction; and a connector on the connection pad, the connector including a connection pin that contacts the concave portion.

According to an embodiment, a thickness of the connection pad in the first direction may decrease from an edge portion of the connection pad, in the second direction, to the central portion of the connection pad.

According to an embodiment, the connection pin may be spaced apart from the edge portion of the connection pad.

According to an embodiment, the inclined surface of the connection pad may be a concave surface, the concave surface including an inclination angle with respect to one surface of the base substrate, and the inclination angle increases from the central portion to the edge portion of the connection pad.

According to an embodiment, the inclined surface of the connection pad may be a convex surface, the convex surface including an inclination angle with respect to one surface of the base substrate, and the inclination angle decreases from the central portion to the edge portion of the connection pad.

According to an embodiment, a thickness, in the first direction, of the central portion of the connection pin may be greater than a thickness, in the first direction, of an edge portion of the connection pin in the second direction.

According to an embodiment, the connection pin may include a protruding portion that protrudes toward the concave portion and contacts the concave portion.

According to an embodiment, the protruding portion may include a triangular cross-sectional shape.

According to an embodiment, the protruding portion may include a curvature in a cross-section.

According to an embodiment, a width of the connection pin in the second direction may be smaller than a width of the connection pad in the second direction.

According to some embodiments of the present disclosure, an electronic device may include: a display panel including a pixel; a circuit board connected to the display panel; a driving controller configured to control driving of the display panel; and a processor configured to output an input image data and an input control signal to the driving controller, wherein the circuit board includes: a base substrate; a connection pad on the base substrate, wherein an upper surface of the connection pad in a first direction includes an inclined surface and a concave portion, the concave portion being at a central portion of the upper surface in a second direction that crosses the first direction; and a connector on the connection pad, the connector including a connection pin that contacts the concave portion.

According to an embodiment, a thickness of the connection pad in the first direction may decrease from an edge portion of the connection pad, in the second direction, to the central portion of the connection pad.

According to an embodiment, the connection pin may be spaced apart from the edge portion of the connection pad.

According to an embodiment, a thickness, in the first direction, of the central portion of the connection pin may be greater than a thickness, in the first direction, of an edge portion of the connection pin in the second direction.

According to an embodiment, the connection pin may include a protruding portion that protrudes toward the concave portion and contacts the concave portion.

According to an embodiment, the protruding portion may include a triangular cross-sectional shape.

According to an embodiment, the protruding portion may include a curvature in a cross-section.

According to some embodiments of the present disclosure, a method may include: providing a connector on a connection pad, wherein an upper surface of the connection pad in a first direction includes an inclined surface and a concave portion, the concave portion being at a central portion of the upper surface in a second direction that crosses the first direction, and the connector includes a connection pin, wherein the providing includes contacting the connection pin to the concave portion of the connection pad.

According to an embodiment, the method may further include: inspecting an electrical characteristic of the connection pin while the connector is on the connection pad.

According to an embodiment, the inspecting may include: contacting an inspection pin of an inspection jig to the connection pin; and inspecting the electrical characteristic of the connection pin through the inspection pin.

A circuit board according to embodiments of the present disclosure may include a connection pad arranged on a base substrate, having an upper surface including an inclined surface and a concave portion formed at a central portion of the upper surface, and a connector arranged on the connection pad and including a connection pin which contacts the concave portion. Accordingly, even if there is misalignment between the connection pad and the connection pin, the connection pin may move to the central portion of the connection pad along the inclined surface under the influence of gravity. As a result, the positional deviation of the connection pin formed on the upper surface of the connection pad may be reduced. In addition, when performing a process of inspecting the connection pin, the contact accuracy of an inspection pin contacting the connection pin may be improved.

In an embodiment, the connection pin may include a protruding portion which protrudes toward the concave portion and contacts the concave portion. In this case, a contact area between the connection pad and the connection pin may be relatively reduced.

Accordingly, when the connection pin moves along the inclined surface, a friction force between the connection pad and the connection pin may be relatively reduced.

### BRIEF DESCRIPTION OF DRAWINGS

Non-limiting example embodiments will be more clearly understood from the following detailed description in conjunction with the accompanying drawings.

FIG. 1 is a block diagram illustrating a display device according to an embodiment of the present disclosure.

FIG. 2 is a plan view illustrating the display device of FIG. 1.

FIG. 3 is an enlarged plan view of an area A of FIG. 2.

FIG. 4 is a perspective view illustrating an example of a connection pad included in a circuit board of FIG. 2.

FIG. 5 is a cross-sectional view illustrating the connection pad of FIG. 4.

FIG. 6 is a perspective view illustrating an example of a connection pin of a connector included in the circuit board of FIG. 2.

FIG. 7 is a cross-sectional view illustrating the connection pin of FIG. 6.

FIG. 8 is a perspective view illustrating the connection pin of FIG. 6 on the connection pad of FIG. 4.

FIG. 9 is a cross-sectional view illustrating the connection pin of FIG. 6 on the connection pad of FIG. 4.

FIGS. 10, 11, 12, and 13 are views for describing a process of inspecting the connection pin of FIG. 6.

FIG. 14 is a cross-sectional view illustrating an example of a connection pad included in the circuit board of FIG. 2.

FIG. 15 is a cross-sectional view illustrating an example of a connection pad included in the circuit board of FIG. 2.

FIG. 16 is a perspective view illustrating an example of a connection pin of a connector included in the circuit board of FIG. 2.

FIG. 17 is a cross-sectional view illustrating the connection pin of FIG. 16.

FIG. 18 is a perspective view illustrating the connection pin of FIG. 16 on the connection pad of FIG. 4.

FIG. 19 is a cross-sectional view illustrating the connection pin of FIG. 16 on the connection pad of FIG. 4.

FIG. 20 is a block diagram illustrating an electronic device according to an embodiment of the present disclosure.

FIG. 21 is a view illustrating an example in which the electronic device of FIG. 20 is implemented as a computer monitor.

FIG. 22 is a view illustrating an example in which the electronic device of FIG. 20 is implemented as a smart phone.

### DETAILED DESCRIPTION

Embodiments of the present disclosure may be variously modified and realized in many different forms, and thus non-limiting example embodiments will be described in detail below and shown in the drawings. However, embodiments of the present disclosure are not limited to the specific example embodiments. All modifications, equivalents, and/or replacements of embodiments of the present disclosure are included in the spirit and scope of the present disclosure.

In the present disclosure, it will be understood that when an element (or area, layer, or portion) is referred to as being “on,” “connected to”, or “coupled to” another element or layer, it can be directly on, connected, or coupled to the other element or layer or intervening elements or layers may be present.

As used herein, the term “and/or” may include any and all combinations of one or more of the associated listed items.

It will be understood that, although the terms “first,” “second,” etc., may be used herein to describe various elements, these elements is not limited by these terms. These terms are only used to distinguish one element from another element. Thus, a first element discussed below could be termed a second element without departing from the teachings of the present disclosure. As used herein, the singular forms, “a,” “an,” and “the” are intended to include the plural forms as well, unless the context clearly indicates otherwise.

Spatially relative terms, such as “beneath,” “below,” “lower,” “above,” “upper,” and the like, may be used herein for ease of description to describe one element or feature's relationship to another elements or features as shown in the figures.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” (or “comprise”) and/or “including” (or “comprising”) when used in this specification, specify the presence of stated features, integers, steps, operations, elements, and/or components, but do not preclude the presence or addition of one or more other features, integers, steps, operations, elements, components, and/or groups thereof.

Hereinafter, non-limiting example embodiments of the present disclosure will be described in detail with reference to the accompanying drawings. The same reference numerals are used for the same components in the drawings, and redundant descriptions of the same components may be omitted.

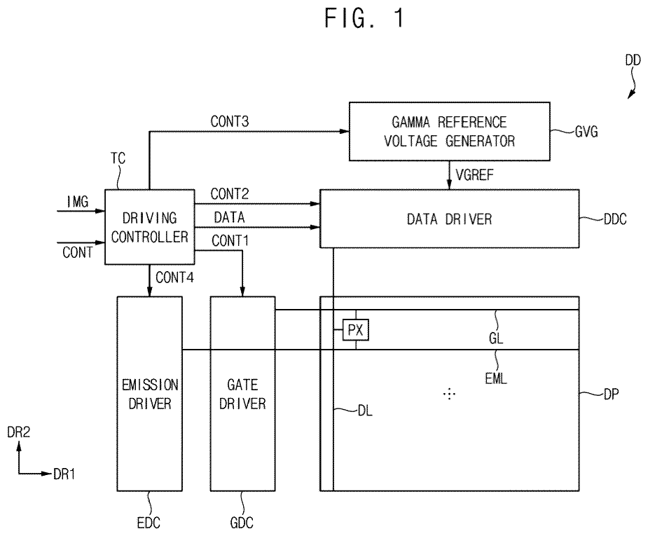

FIG. 1 is a block diagram illustrating a display device according to an embodiment of the present disclosure.

In this specification, a plane may be defined by a first direction DR1 and a second direction DR2 intersecting the first direction DR1. For example, the first direction DR1 and the second direction DR2 may be perpendicular to each other. A direction normal to the plane may be a third direction DR3. In other words, the third direction DR3 may be perpendicular to each of the first direction DR1 and the second direction DR2.

Referring to FIG. 1, a display device DD according to an embodiment of the present disclosure may include a display panel DP and a panel driver that drives the display panel DP. The panel driver may include a driving controller TC, a gate driver GDC, a gamma reference voltage generator GVG, a data driver DDC, and an emission driver EDC.

The display panel DP may include gate lines GL, data lines DL, emission lines EML, and pixels PX. The pixels PX may be electrically connected to the gate lines GL, the data lines DL, and the emission lines EML. Each of the pixels PX may emit light in response to a driving signal. For example, the pixels PX may be arranged in a matrix form along the first direction DR1 and the second direction DR2. Each of the gate lines GL may extend in the first direction DR1. Each of the emission lines EML may extend in the first direction DR1. Each of the data lines DL may extend in the second direction DR2.

The driving controller TC may control the driving of the display panel DP. The driving controller TC may receive an input image data IMG and an input control signal CONT from an external device. For example, the input image data IMG may include red image data, green image data, and blue image data. The input image data IMG may further include white image data. The input control signal CONT may include a vertical synchronization signal, a horizontal synchronization signal, a data enable signal, a master clock signal, or the like.

The driving controller TC may generate a first control signal CONT1, a second control signal CONT2, a third control signal CONT3, a fourth control signal CONT4, and a data signal DATA based on the input image data IMG and the input control signal CONT. The driving controller TC may output the first control signal CONT1 to the gate driver GDC. The first control signal CONT1 may include a vertical start signal and a scan clock signal. The driving controller TC may output the second control signal CONT2 and the data signal DATA to the data driver DDC. The second control signal CONT2 may include a horizontal start signal and a load signal. The driving controller TC may output the third control signal CONT3 to the gamma reference voltage generator GVG. The driving controller TC may output the fourth control signal CONT4 to the emission driver EDC.

The gate driver GDC may generate gate signals in response to the first control signal CONT1. The gate driver GDC may output the gate signals to the gate lines GL.

The gamma reference voltage generator GVG may generate a gamma reference voltage VGREF in response to the third control signal CONT3. The gamma reference voltage generator GVG may provide the gamma reference voltage VGREF to the data driver DDC. For example, the gamma reference voltage generator GVG may be arranged in the driving controller TC or arranged in the data driver DDC.

The data driver DDC may receive the second control signal CONT2 and the data signal DATA from the driving controller TC, and may receive the gamma reference voltage VGREF from the gamma reference voltage generator GVG. The data driver DDC may convert the data signal DATA into an analog form of a data voltage using the gamma reference voltage VGREF. The data driver DDC may output the data voltage to the data lines DL.

The emission driver EDC may generate emission signals in response to the fourth control signal CONT4. The emission driver EDC may output the emission signals to the emission lines EML.

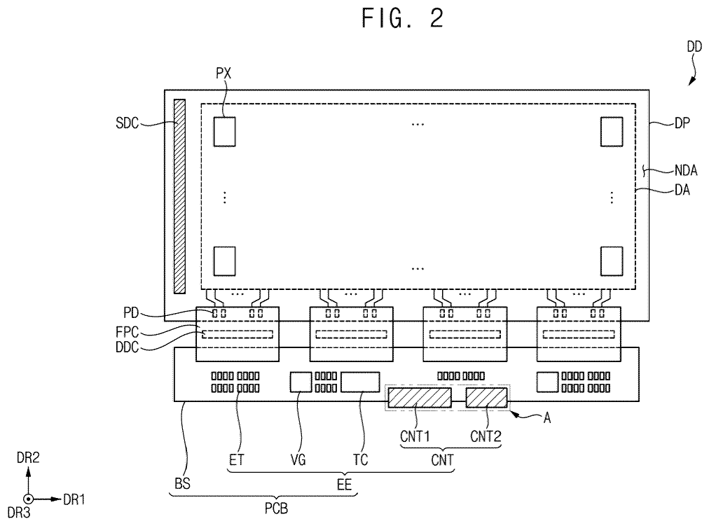

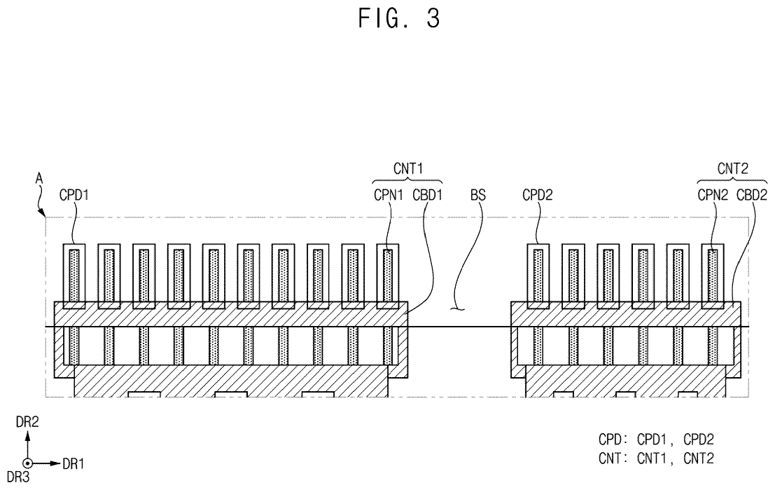

FIG. 2 is a plan view illustrating the display device of FIG. 1. FIG. 3 is an enlarged plan view of an area A of FIG. 2.

Referring to FIG. 2, the display device DD according to an embodiment of the present disclosure may be a device that is activated in response to an electrical signal. For example, the display device DD may be a medium-or large-sized display device used in a medium-or large-sized electronic device such as a laptop, a tablet PC, a television, a computer monitor, a vehicle monitor, and an exterior billboard. In FIG. 2, the display device DD is illustrated as an example of the medium-to large-sized display device. However, embodiments of the present disclosure are not limited thereto. For example, the display device DD may be a small-sized display device used in a small-sized electronic device such as a smartphone, a cell phone, a smart watch, a game console, and a camera.

For example, the display device DD may have a rectangular shape including a long side extending in the first direction DR1 and a short side extending in the second direction DR2 in a plan view. However, embodiments of the present disclosure are not limited thereto. For example, the display device DD may have any one from among a circular planar shape, a polygonal planar shape, and an elliptical planar shape.

The display device DD may include the display panel DP, a scan driver SDC, the data driver DDC, a flexible circuit board FPC, and a circuit board PCB.

The display panel DP may include a display area DA and a non-display area NDA. The display area DA may be defined as an area that displays an image by generating light or adjusting the transmittance of light provided from an external light source. The display panel DP may include the pixels PX arranged in the display area DA. Each of the pixels PX may emit light in response to a driving signal.

For example, the display panel DP may be a liquid crystal display (LCD) panel, an electrophoretic display panel, an organic light emitting diode (OLED) panel, a light emitting diode (LED) panel, a field emission display (FED) panel, or the like. However, embodiments of the present disclosure are not limited thereto. For example, the display device DD may include a display panel of one of various types.

The non-display area NDA may be adjacent to the display area DA. The non-display area NDA may surround at least a portion of the display area DA in a plan view (e.g., of the display device DD). For example, the non-display area NDA may entirely surround the display area DA in a plan view (e.g., of the display device DD). The non-display area NDA may be defined as an area that does not display an image. The display panel DP may include pads PD arranged in the non-display area NDA. For example, the pads PD may be arranged in a portion of the non-display area NDA adjacent to a lower side of the display area DA, but embodiments of the present disclosure are not limited thereto.

The scan driver SDC may be arranged in the non-display area NDA on the display panel DP. For example, the scan driver SDC may be arranged in a portion of the non-display area NDA adjacent to a left side of the display area DA, but embodiments of the present disclosure are not limited thereto. The scan driver SDC may generate the gate signals and may output the gate signals to the gate lines DL (see FIG. 1). In addition, the scan driver SDC may generate the emission signals and may output the emission signals to the emission lines EML (see FIG. 1). That is, the scan driver SDC may include the gate driver GDC and the emission driver EDC of FIG. 1.

The flexible circuit board FPC may be arranged in the non-display area NDA on the display panel DP. Specifically, the flexible circuit board FPC may be attached to the display panel DP such that a portion of the flexible circuit board FPC overlaps with the pads PD. The flexible circuit board FPC may be connected to the pads PD through an anisotropic conductive film. That is, the flexible circuit board FPC may be electrically connected to the pads PD.

In an embodiment, the flexible circuit board FPC may be provided in plural, and the plurality of flexible circuit boards FPC may be arranged along the first direction DR1. However, the number of the flexible circuit boards FPC included in the display device DD is not limited to the number illustrated, and the number of the flexible circuit boards FPC may be varied according to embodiments.

In an embodiment, the flexible circuit board FPC may include a base film. The base film may include a flexible material. For example, the base film may include a polymer material such as polyimide (PI), polyethylene terephthalate (PET), polyethylene naphthalate (PEN), or the like. However, embodiments of the present disclosure are not limited thereto.

As the base film is flexible, the flexible circuit board FPC may be bent toward a back surface of the display panel DP. In addition, as the flexible circuit board FPC is bent toward the back surface of the display panel DP, the circuit board PCB may overlap with the display panel DP in a plan view (e.g., of the display device DD).

The flexible circuit board FPC may include output pads arranged on the base film and respectively connected to the pads PD, input pads connected to the circuit board PCB, and connection lines connecting the output pads and the input pads to the data driver DDC. The flexible circuit board FPC may provide an electrical signal provided from the circuit board PCB and the data driver DDC to the display panel DP.

In an embodiment, the data driver DDC may be mounted on the base film of the flexible circuit board FPC. The data driver DDC may provide a driving signal to the pixels PX. The driving signal may include various signals for driving the pixels PX, such as a driving voltage, the data voltage, or the like. The driving signal may be transmitted to the pixels PX through the data driver DDC, the flexible circuit board FPC, and the pads PD. For example, the data driver DDC of FIG. 2 may correspond to the data driver DDC of FIG. 1.

In an embodiment, the flexible circuit board FPC may be omitted. In this case, the data driver DDC may be mounted in the non-display area NDA on the display panel DP, or may be mounted on the circuit board PCB.

The circuit board PCB may be electrically connected to the flexible circuit board FPC. Specifically, the flexible circuit board FPC may be attached to the circuit board PCB such that a portion of the flexible circuit board FPC overlaps with the circuit board PCB. For example, the circuit board PCB may be a printed circuit board.

In an embodiment, the flexible circuit board FPC may be omitted. In this case, the circuit board PCB may be attached to the display panel DP such that a portion of the circuit board PCB overlaps with the pads PD. The circuit board PCB may be directly connected to the pads PD through an anisotropic conductive film.

The circuit board PCB may include a base substrate BS and electronic elements EE arranged on the base substrate BS. Specifically, the electronic elements EE may be mounted on an upper surface of the base substrate BS. In addition, the circuit board PCB may include circuit board connection pads electrically connected to the input pads of the flexible circuit board FPC, respectively.

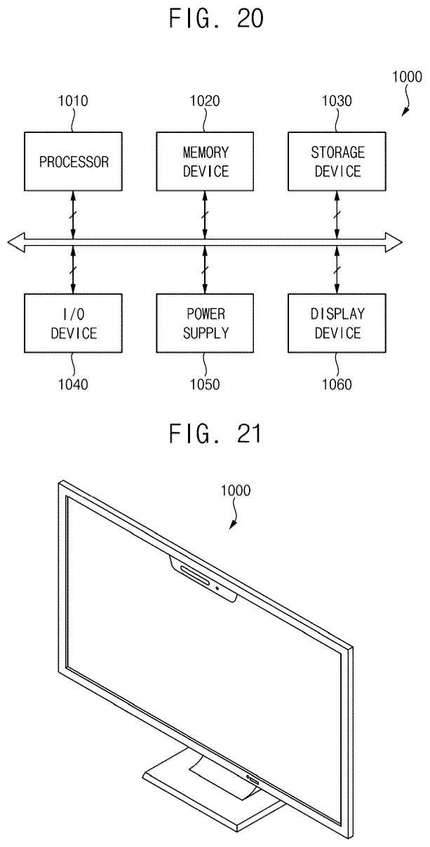

The electronic elements EE may include a voltage generator VG, the driving controller TC, at least one connector CNT, and a plurality of elements ET. The voltage generator VG may generate a voltage that is applied to the pixels PX. The driving controller TC may control the operations of the scan driver SDC and the data driver DDC. For example, the driving controller TC of FIG. 2 may correspond to (e.g., may be) the driving controller TC of FIG. 1. The plurality of elements ET may include electrical elements such as resistors, capacitors, inductors, or the like. The at least one connector CNT may include a first connector CNT1 and a second connector CNT2. The first connector CNT1 and the second connector CNT2 may electrically connect an external device and the circuit board PCB. For example, the external device may be a power supply 1050 (see FIG. 20), but embodiments of the present disclosure are not limited thereto.

Referring further to FIG. 3, the circuit board PCB may further include at least one connection pad CPD arranged on the base substrate BS. Specifically, the at least one connection pad CPD may be formed on an upper surface of the base substrate BS. The at least one connection pad CPD may include a first connection pad CPD1 and a second connection pad CPD2. The first connection pad CPD1 may be connected to the first connector CNT1, and the second connection pad CPD2 may be connected to the second connector CNT2.

In an embodiment, the first connection pad CPD1 may be provided in plural, and the plurality of first connection pad CPD1 may be arranged along the first direction DR1. For example, a width (e.g., a length in the first direction DR1) of each of the first connection pads CPD1 may be about 300 micrometers. A separation distance between neighboring ones of the first connection pads CPD1 may be about 200 micrometers. However, embodiments of the present disclosure are not limited thereto.

In addition, the second connection pad CPD2 may be provided in plural, and the plurality of second connection pads CPD2 may be arranged along the first direction DR1. The second connection pads CPD2 may be spaced apart from the first connection pads CPD1. For example, a width (e.g., a length in the first direction DR1) of each of the second connection pads CPD2 may be about 300 micrometers. A separation distance between neighboring ones of the second connection pads CPD2 may be about 200 micrometers. However, embodiments of the present disclosure are not limited thereto.

The first connector CNT1 may be arranged on the first connection pads CPD1. The first connector CNT1 may include a first connector body portion CBD1 and a first connection pin CPN1 connected to the first connector body portion CBD1. In an embodiment, the first connection pin CPN1 may be provided in plural, and the plurality of first connection pins CPN1 may be arranged along the first direction DR1. For example, the first connector CNT1 may include 60 first connection pins CPN1. However, embodiments of the present disclosure are not limited thereto, and the number of the first connection pins CPN1 may be varied according to embodiments.

In an embodiment, in a plan view (e.g., of the display device DD), an area of one first connection pin CPN1 may be smaller than an area of one first connection pad CPD1. In addition, a width (e.g., a length in the first direction DR1) of one first connection pin CPN1 may be smaller than the width of one first connection pad CPD1. For example, the width of the first connection pin CPN1 may be about 200 micrometers and the width of the first connection pad CPD1 may be about 300 micrometers, but embodiments of the present disclosure are not limited thereto.

The first connection pins CPN1 may contact the first connection pads CPD1, respectively. For example, the first connection pins CPN1 may correspond one-to-one with the first connection pads CPD1. Specifically, the first connector CNT1 may be arranged on the first connection pads CPD1 such that the first connection pins CPN1 contact the first connection pads CPD1, respectively. The first connection pins CPN1 may be bonded to the first connection pads CPD1 through a reflow process, and the first connector CNT1 may be mounted on the upper surface of the base substrate BS.

The second connector CNT2 may be arranged on the second connection pads CPD2. The second connector CNT2 may include a second connector body portion CBD2 and a second connection pin CPN2 connected to the second connector body portion CBD2. In an embodiment, the second connection pin CPN2 may be provided in plural, and the plurality of second connection pins CPN2 may be arranged along the first direction DR1. For example, the second connector CNT2 may include 40 second connection pins CPN2. However, embodiments of the present disclosure are not limited thereto, and the number of the second connection pins CPN2 may be varied according to embodiments.

In an embodiment, in a plan view (e.g., of the display device DD), an area of one second connection pin CPN2 may be smaller than an area of one second connection pad CPD2. In addition, a width (e.g., a length in the first direction DR1) of one second connection pin CPN2 may be smaller than the width of one second connection pad CPD2. For example, the width of the second connection pin CPN2 may be about 120 micrometers and the width of the second connection pad CPD2 may be about 300 micrometers, but embodiments of the present disclosure are not limited thereto.

The second connection pins CPN2 may contact the second connection pads CPD2, respectively. For example, the second connection pins CPN2 may correspond one-to-one with the second connection pads CPD2. Specifically, the second connector CNT2 may be arranged on the second connection pads CPD2 such that the second connection pins CPN2 contact the second connection pads CPD2, respectively. The second connection pins CPN2 may be bonded to the second connection pads CPD2 through a reflow process, and the second connector CNT2 may be mounded on the upper surface of the base substrate BS.

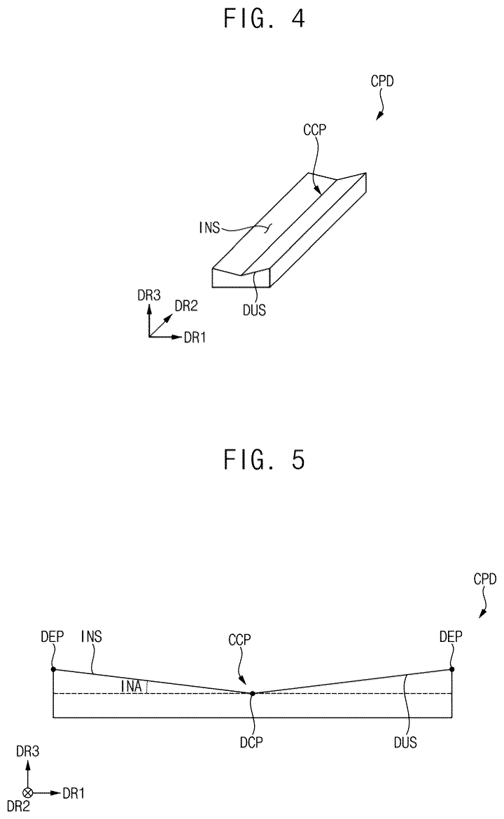

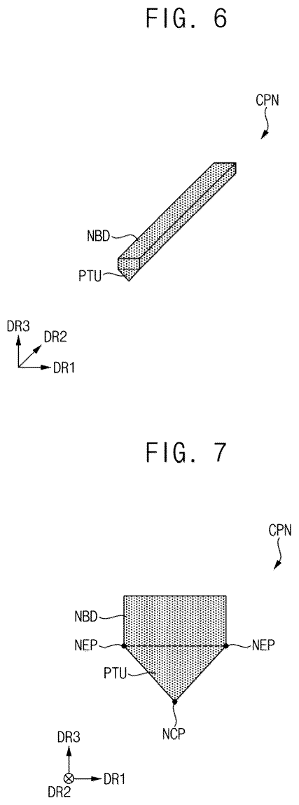

The first connection pad CPD1 may have substantially the same shape as a shape of the second connection pad CPD2. In addition, the first connection pin CPN1 may have a similar shape to a shape of the second connection pin CPN2, except that the width of the first connection pin CPN1 and the width of the second connection pin CPN2 may be different from each other. Therefore, the following description will focus on the first connection pad CPD1 and the first connection pin CPN1. Hereinafter, for convenience of description, the first connection pad CPD1 is referred to as a connection pad CPD (see FIG. 4) and the first connection pin CPN1 is referred to as a connection pin CPN (see FIG. 6).

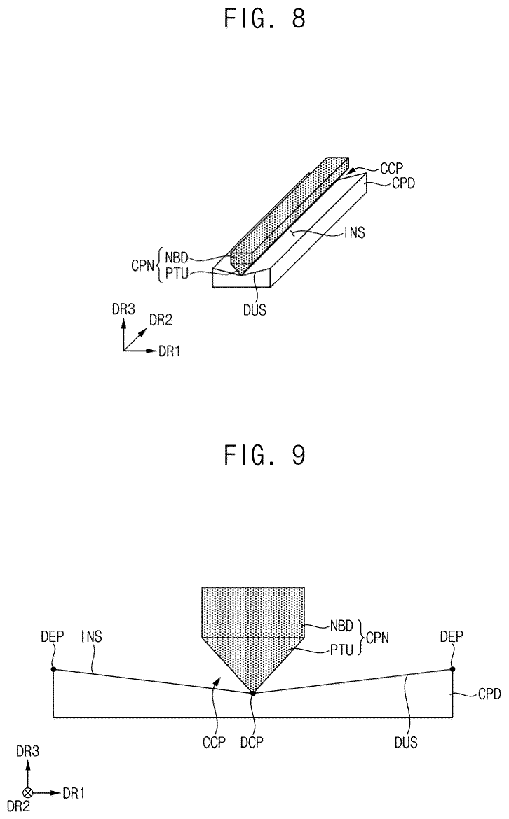

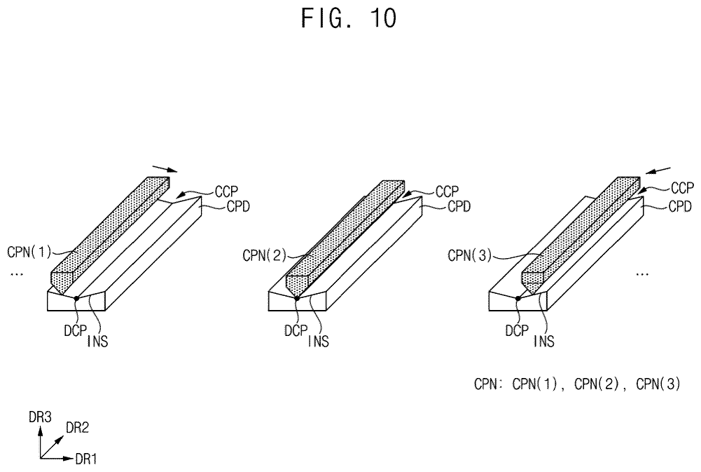

FIG. 4 is a perspective view illustrating an example of a connection pad included in the circuit board of FIG. 2. FIG. 5 is a cross-sectional view illustrating the connection pad of FIG. 4. FIG. 6 is a perspective view illustrating an example of a connection pin of a connector included in the circuit board of FIG. 2. FIG. 7 is a cross-sectional view illustrating the connection pin of FIG. 6. FIG. 8 is a perspective view illustrating the connection pin of FIG. 6 on the connection pad of FIG. 4. FIG. 9 is a cross-sectional view illustrating the connection pin of FIG. 6 on the connection pad of FIG. 4.

Referring to FIGS. 3, 4, and 5, the circuit board PCB may include the connection pad CPD arranged on the base substrate BS. Specifically, the connection pad CPD may be formed on the upper surface of the base substrate BS. The connection pad CPD may have a width in the first direction DR1 and may extend in the second direction DR2. In an embodiment, an upper surface DUS of the connection pad CPD may include an inclined surface INS, and the connection pad CPD may include a concave portion CCP formed at a central portion DCP of the upper surface DUS. Accordingly, a thickness (e.g., a length in the third direction DR3) of the central portion DCP of the connection pad CPD may be smaller than a thickness of an edge portion DEP of the connection pad CPD. In an embodiment, the thickness of the connection pad CPD may decrease from the edge portion DEP to the central portion DCP.

According to an embodiment, the inclined surface INS may surround the concave portion CCP in at least one horizontal direction. For example, with reference to FIG. 5, the inclined surface INS may be at respective sides of the concave portion CCP in the first direction DR1 and a direction opposite to the first direction DR1, and the thickness of the central portion DCP of the connection pad CPD may be smaller than a thickness of two edge portions DEP of the connection pad CPD at respective ends of the connection pad CPD in the first direction DR1 and the direction opposite to the first direction DR1. In such case, the inclined surface INS may be referred to as two inclined surfaces INS at the respective sides of the concave portion CCP.

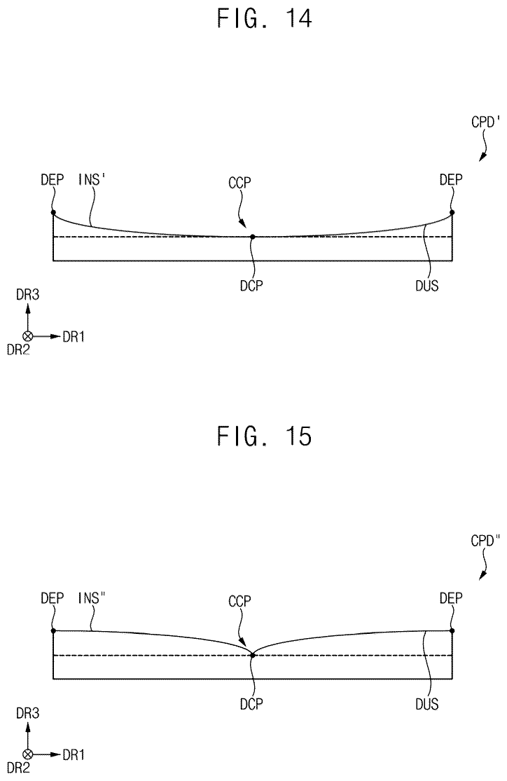

In an embodiment, the inclined surface INS may have an inclination angle INA that is constant, the inclination angle INA being with respect to one surface of the base substrate BS (or a horizontal plane of the base substrate BS). In other words, the inclined surface INS may have a straight line shape in a cross-section. However, embodiments of the present disclosure are not limited thereto, and the inclination angle INA of the inclined surface INS with respect to the one surface of the base substrate BS may increase or decrease from the central portion DCP to the edge portion DEP. In this case, the inclined surface INS may have a curvature (e.g., a predetermined curvature) in a cross-section. A detailed description thereof will be provided below with reference to FIGS. 14 and 15.

Referring further to FIGS. 6 and 7, the connection pin CPN of the connector CNT may have a width in the first direction DR1 and may extend in the second direction DR2. In an embodiment, the connection pin CPN may include a pin body portion NBD and a protruding portion PTU connected to the pin body portion NBD. In other words, a thickness (e.g., a length in the third direction DR3) of a central portion NCP of the connection pin CPN may be greater than a thickness of an edge portion NEP of the connection pin CPN. In an embodiment, the thickness of the connection pin CPN may increase from the edge portion NEP to the central portion NCP.

According to an embodiment, the connection pin CPN may include two edge portions NEP at respective sides of the central portion NCP in the first direction DR1 and the direction opposite to the first direction DR1, and the thickness of the connection pin CPN may increase from the edge portions NEP to the central portion NCP.

Referring further to FIGS. 8 and 9, the connection pin CPN may be arranged on the connection pad CPD. The connection pin CPN may contact the upper surface DUS of the connection pad CPD.

In an embodiment, the connection pin CPN may contact the concave portion CCP of the connection pad CPD. Specifically, the connection pin CPN and the connection pad CPD may be aligned such that the protruding portion PTU faces the concave portion CCP, and the protruding portion PTU may contact the concave portion CCP. In an embodiment, the connection pin CPN may be spaced apart from the edge portion DEP of the connection pad CPD. In other words, the connection pin CPN may not contact the edge portion DEP of the connection pad CPD.

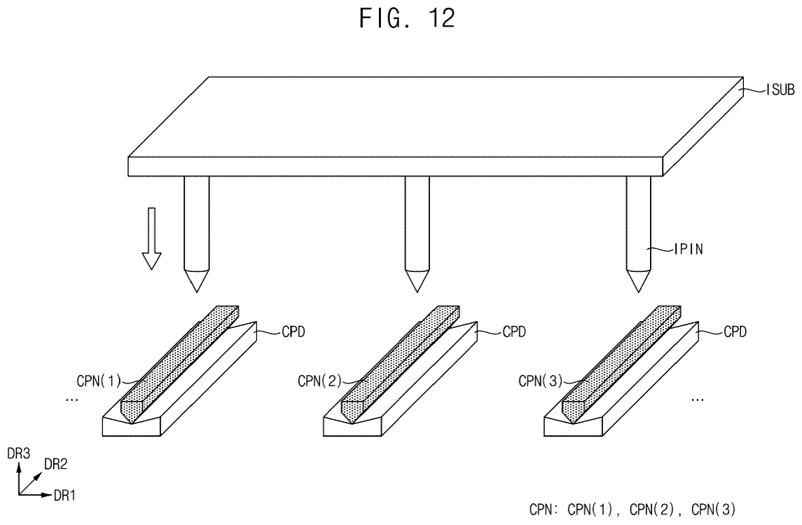

According to embodiments of the present disclosure, the upper surface DUS of the connection pad CPD may include the two inclined surfaces INS, and the concave portion CCP may be formed at the central portion DCP of the upper surface DUS. That is, the inclined surface INS positioned at a left side of the concave portion CCP and the inclined surface INS positioned at a right side of the concave portion CCP may be substantially symmetrical with respect to the central portion DCP. Accordingly, even if there is misalignment between the connection pad CPD and the connection pin CPN (e.g., even if the connection pin CPN is arranged to a left side or a right side of the central portion DCP of the connection pad CPD), the connection pin CPN may move to the central portion DCP of the connection pad CPD along the inclined surface INS under the influence of gravity. As a result, the positional deviation of the connection pin CPN formed on (or bonded to) the upper surface DUS of the connection pad CPD may be reduced. In addition, when performing a process of inspecting the connection pin CPN, the contact accuracy of an inspection pin (e.g., an inspection pin IPIN of FIG. 12) contacting the connection pin CPN may be improved. A detailed description thereof will be provided below with reference to FIGS. 10 to 13.

In an embodiment, the protruding portion PTU may have a triangular cross-sectional shape. In this case, compared to a case where the connection pin CPN has an overall rectangular cross-sectional shape, a contact area between the connection pad CPD and the connection pin CPN (specifically, the protruding portion PTU) may be relatively reduced.

Accordingly, when the connection pin CPN moves along the inclined surface INS, a friction force between the connection pad CPD and the connection pin CPN (specifically, the protruding portion PTU) may be relatively reduced. However, the cross-sectional shape of the protruding portion PTU is not limited thereto.

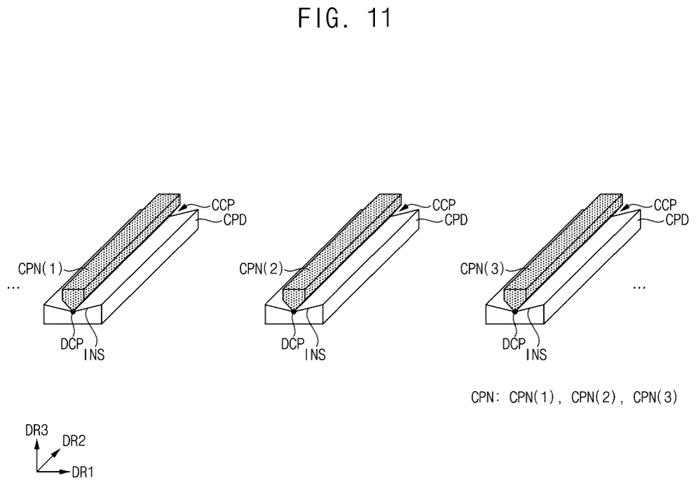

FIGS. 10, 11, 12, and 13 are views for describing a process of inspecting the connection pin of FIG. 6. For example, FIG. 10 illustrates the position of the connection pin CPN according to an alignment process before a reflow process is performed, and FIG. 11 illustrates the position of the connection pin CPN after the reflow process is performed. In FIGS. 10 to 13, three connection pins CPN(1), CPN(2), and CPN(3) are illustrated for convenience of description.

Referring to FIG. 10, during a process of arranging the connection pin CPN on the connection pad CPD, the alignment between the connection pads CPD and the connection pin CPN may be misaligned depending on an overlay distribution. For example, it may be preferable that the connection pin CPN be arranged at the central portion DCP of the connection pad CPD, such as shown by a center connection pin CPN(2) in FIG. 10, but the connection pin CPN may also be arranged at a left side or a right side of the central portion DCP of the connection pad CPD, such as shown by a left connection pin CPN(1) or a right connection pin CPN(3) of FIG. 10.

Referring further to FIG. 11, as the connection pad CPD includes the inclined surface INS, the connection pin CPN may move to the central portion DCP of the connection pad CPD along the inclined surface INS under the influence of gravity. In addition, even if the connection pin CPN moves on the connection pad CPD during the reflow process, the inclined surface INS may induce the connection pin CPN to move to the central portion DCP of the connection pad CPD. Accordingly, after the reflow process is performed, all three connection pins (e.g., the left connection pin CPN(1), the center connection pin CPN(2), and the right connection pin CPN(3)) may be positioned at the central portion DCP of the connection pad CPD.

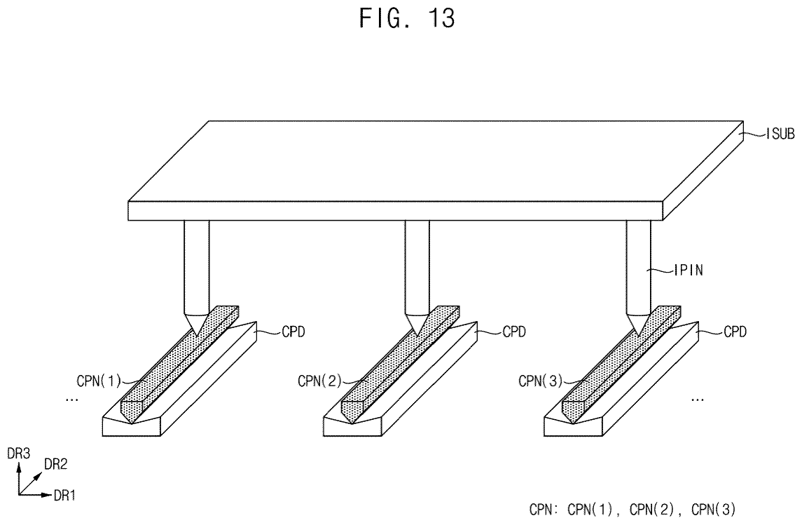

Referring to FIGS. 12 and 13, an inspection jig may be used to perform an inspection process of the connection pin CPN. The inspection jig may include an inspection substrate ISUB and an inspection pin IPIN connected to the inspection substrate ISUB. The inspection pin IPIN may be provided in plural, and the plurality of inspection pins IPIN may be arranged along the first direction DR1.

To inspect the connection pins CPN, the inspection substrate ISUB may be raised or lowered. For example, the inspection substrate ISUB may move in the third direction DR3 or in an opposite direction of the third direction DR3. When the inspection substrate ISUB is lowered, the inspection pins IPIN connected to the inspection substrate ISUB may be lowered together.

As the inspection pins IPIN are lowered, the inspection pins IPIN may contact the connection pins CPN, respectively. Accordingly, the inspection jig may inspect electrical characteristics of the connection pins CPN. For example, the inspection jig may inspect the electrical characteristics through the connection pins CPN. For example, the inspection pins IPIN may correspond one-to-one with the connection pins CPN.

As described above, as the connection pad CPD includes the inclined surface INS, all three connection pins (e.g., the left connection pin CPN(1), the center connection pin CPN(2), and the right connection pin CPN(3)) may be positioned at the central portion DCP of the connection pad CPD after the reflow process is performed. That is, the positional deviation of the connection pin CPN formed on (or bonded to) the upper surface DCP of the connection pad CPD may be reduced. In addition, as the connection pin CPN is positioned at the central portion DCP of the connection pad CPD, the contact accuracy of the inspection pin IPIN contacting the connection pin CPN may be improved, and the inspection accuracy for the connection pin CPN may be improved.

FIG. 14 is a cross-sectional view illustrating an example of a connection pad included in the circuit board of FIG. 2.

Referring to FIGS. 2 and 14, in an embodiment, a circuit board PCB may include at least one connection pad CPD′ arranged on a base substrate BS. Specifically, the at least one connection pad CPD′ may be formed on an upper surface of the base substrate BS. The connection pad CPD′ may be substantially the same as the connection pad CPD described above with reference to FIGS. 4 and 5, except that the connection pad CPD′ may include an inclined surface INS′, and the inclined surface INS′ may have a curvature (e.g., a predetermined curvature) in a cross-section. Hereinafter, redundant descriptions of the connection pad CPD described above with reference to FIGS. 4 and 5 may be omitted or may be summarized.

An upper surface DUS of the connection pad CPD′ may include the inclined surface INS′, and the connection pad CPD′ may include a concave portion CCP formed at a central portion DCP of the upper surface DUS. Accordingly, a thickness of the central portion DCP of the connection pad CPD′ may be smaller than a thickness of an edge portion DEP of the connection pad CPD′. In an embodiment, the thickness of the connection pad CPD′ may decrease from the edge portion DEP to the central portion DCP. According to an embodiment, the inclined surface INS′ may surround the concave portion CCP in at least one horizontal direction. For example, with reference to FIG. 14, the inclined surface INS′ may be at respective sides of the concave portion CCP in the first direction DR1 and the direction opposite to the first direction DR1, and the thickness of the central portion DCP of the connection pad CPD′ may be smaller than a thickness of two edge portions DEP of the connection pad CPD′ at respective ends of the connection pad CPD′ in the first direction DR1 and the direction opposite to the first direction DR1. In such case, the inclined surface INS′ may be referred to as two inclined surfaces INS′ at the respective sides of the concave portion CCP.

In an embodiment, the inclined surface INS′may have a curvature (e.g., a predetermined curvature) in a cross-section. For example, the inclined surface INS′ may be a concave surface whose inclination angle (e.g., the inclination angle INA of FIG. 5) with respect to one surface of the base substrate BS (or a horizontal plane of the base substrate BS) gradually increases from the central portion DCP to the edge portion DEP. The inclined surface INS′ may induce the connection pin to move to the central portion DCP of the connection pad CPD′ under the influence of gravity.

FIG. 15 is a cross-sectional view illustrating an example of a connection pad included in the circuit board of FIG. 2.

Referring to FIGS. 2 and 15, in an embodiment, a circuit board PCB may include at least one connection pad CPD″ arranged on a base substrate BS. Specifically, the at least one connection pad CPD″ may be formed on an upper surface of the base substrate BS. The connection pad CPD″ may be substantially the same as the connection pad CPD described above with reference to FIGS. 4 and 5, except that an inclined surface INS″ may have a curvature (e.g., a predetermined curvature) in a cross-section. Hereinafter, redundant descriptions of the connection pad CPD described above with reference to FIGS. 4 and 5 may be omitted or may be summarized.

An upper surface DUS of the connection pad CPD″ may include the inclined surface INS″, and the connection pad CPD″ may include a concave portion CCP formed at a central portion DCP of the upper surface DUS. Accordingly, a thickness of the central portion DCP of the connection pad CPD″ may be smaller than a thickness of an edge portion DEP of the connection pad CPD″. In an embodiment, the thickness of the connection pad CPD″ may decrease from the edge portion DEP to the central portion DCP.

According to an embodiment, the inclined surface INS″ may surround the concave portion CCP in at least one horizontal direction. For example, with reference to FIG. 15, the inclined surface INS″ may be at respective sides of the concave portion CCP in the first direction DR1 and the direction opposite to the first direction DR1, and the thickness of the central portion DCP of the connection pad CPD″ may be smaller than a thickness of two edge portions DEP of the connection pad CPD″ at respective ends of the connection pad CPD″ in the first direction DR1 and the direction opposite to the first direction DR1. In such case, the inclined surface INS″ may be referred to as two inclined surfaces INS″ at the respective sides of the concave portion CCP.

In an embodiment, the inclined surface INS″ may have a curvature (e.g., a predetermined curvature) in a cross-section. For example, the inclined surface INS″ may be a convex surface whose inclination angle (e.g., the inclination angle INA of FIG. 5) with respect to one surface of the base substrate BS (or a horizontal plane of the base substrate BS) gradually decreases from the central portion DCP to the edge portion DEP. The inclined surface INS″ may induce the connection pin to move to the central portion DCP of the connection pad CPD″ under the influence of gravity.

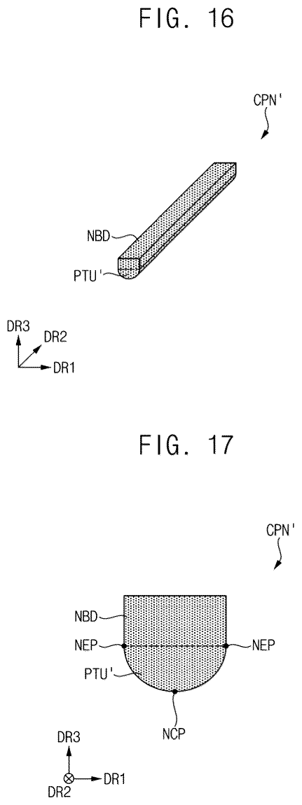

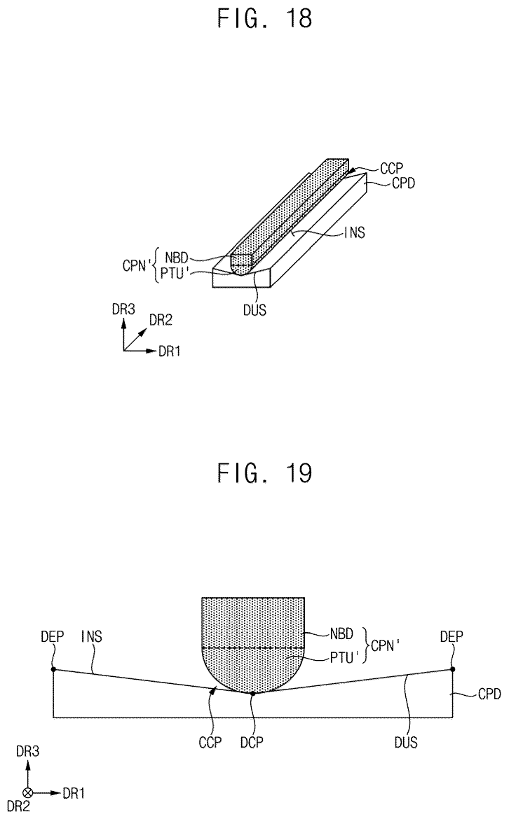

FIG. 16 is a perspective view illustrating an example of a connection pin of a connector included in the circuit board of FIG. 2. FIG. 17 is a cross-sectional view illustrating the connection pin of FIG. 16. FIG. 18 is a perspective view illustrating the connection pin of FIG. 16 on the connection pad of FIG. 4. FIG. 19 is a cross-sectional view illustrating the connection pin of FIG. 16 on the connection pad of FIG. 4.

Referring to FIGS. 2, 16, and 17, in an embodiment, a circuit board PCB may include a connector CNT, and the connector CNT may include at least one connection pin CPN′. The connection pin CPN′ may be substantially the same as the connection pin CPN described above with reference to FIGS. 6 and 7, except for the cross-sectional shape of a protruding portion PTU′. Hereinafter, redundant descriptions of the connection pin CPN described above with reference to FIGS. 6 and 7 may be omitted or may be summarized.

The connection pin CPN′ may include a pin body portion NBD and the protruding portion PTU′ connected to the pin body portion NBD. In other words, a thickness of a central portion NCP of the connection pin CPN′ may be greater than a thickness of an edge portion NEP of the connection pin CPN′. In an embodiment, the thickness of the connection pin CPN′ may increase from the edge portion NEP to the central portion NCP.

According to an embodiment, the connection pin CPN′ may include two edge portions NEP at respective sides of the central portion NCP in the first direction DR1 and the direction opposite to the first direction DR1, and the thickness of the connection pin CPN′ may increase from the edge portions NEP to the central portion NCP.

In an embodiment, the protruding portion PTU′ may have a curvature (e.g., a predetermined curvature) in a cross-section. For example, the protruding portion PTU′ may have a semicircular or semi-elliptical shape in a cross-section. However, embodiments of the present disclosure are not limited thereto.

Referring further to FIGS. 18 and 19, the connection pin CPN′ may be arranged on the connection pad CPD. The connection pin CPN′ may contact the upper surface DUS of the connection pad CPD.

The connection pin CPN′ may contact the concave portion CCP of the connection pad CPD. Specifically, the connection pin CPN′ and the connection pad CPD may be aligned such that the protruding portion PTU′ faces the concave portion CCP, and the protruding portion PTU′ may contact the concave portion CCP. In an embodiment, the connection pin CPN′ may be spaced apart from the edge portion DEP of the connection pad CPD.

According to embodiments of the present disclosure, the upper surface DUS of the connection pad CPD may include the inclined surface INS, and the concave portion CCP may be formed at the central portion DCP of the upper surface DUS. Accordingly, even if there is misalignment between the connection pad CPD and the connection pin CPN′ (e.g., even if the connection pin CPN′ is arranged to a left side or a right side of the central portion DCP of the connection pad CPD), the connection pin CPN′ may move to the central portion DCP of the connection pad CPD along the inclined surface INS under the influence of gravity.

As described above, the protruding portion PTU′ may have a curvature (e.g., a predetermined curvature) in a cross-section. For example, the protruding portion PTU′ may have a semicircular or semi-elliptical shape in a cross-section. In this case, compared to a case where the connection pin CPN′ has an overall rectangular cross-sectional shape, a contact area between the connection pad CPD and the connection pin CPN′ (specifically, the protruding portion PTU′) may be relatively reduced. Accordingly, when the connecting pin CPN′ moves along the inclined surface INS, a friction force between the connecting pad CPD and the connecting pin CPN′ (specifically, the protruding portion PTU′) may be relatively reduced.

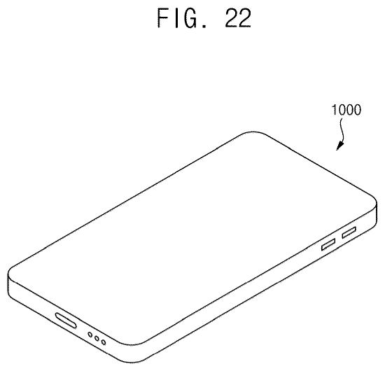

FIG. 20 is a block diagram illustrating an electronic device according to an embodiment of the present disclosure. FIG. 21 is a view illustrating an example in which the electronic device of FIG. 20 is implemented as a computer monitor. FIG. 22 is a view illustrating an example in which the electronic device of FIG. 20 is implemented as a smart phone.

Referring to FIGS. 20, 21, and 22, an electronic device 1000 may include a processor 1010, a memory device 1020, a storage device 1030, an input/output (I/O) device 1040, a power supply 1050, and a display device 1060. The display device 1060 may be the display device DD of FIGS. 1 and 2. The electronic device 1000 may further include a plurality of ports for communicating with a video card, a sound card, a memory card, a universal serial bus (“USB”) device, other systems, or the like.

In an embodiment, as illustrated in FIG. 21, the electronic device 1000 may be implemented as a computer monitor. In an embodiment, as illustrated in FIG. 22, the electronic device 1000 may be implemented as a smart phone. However, the electronic device 1000 is not limited thereto. For example, the electronic device 1000 may be implemented as a smart pad, a smart watch, a car navigation system, a laptop, a head mounted display (HMD) device, or the like.

The processor 1010 may perform various computing functions. The processor 1010 may be a microprocessor, a central processing unit (CPU), an application processor (AP), or the like. The processor 1010 may be coupled to other components through an address bus, a control bus, a data bus, or the like. In an embodiment, the processor 1010 may be coupled to an extended bus such as a peripheral component interconnection (PCI) bus. The processor 1010 may output the input image data IMG and the input control signal CONT to the driving controller TC of FIG. 1.

The memory device 1020 may store data for operations of the electronic device 1000. For example, the memory device 1020 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like and/or at least one volatile memory device such as a dynamic random access memory (DRAM) device, a static random access memory (SRAM) device, a mobile DRAM device, or the like.

The storage device 1030 may include a solid-state drive (SSD) device, a hard disk drive (HDD) device, a CD-ROM device, or the like. The I/O device 1040 may include an input device such as a keyboard, a keypad, a mouse device, a touch-pad, a touch-screen, or the like, and an output device such as a printer, a speaker, or the like. In some embodiments, the I/O device 1040 may include the display device 1060.

The power supply 1050 may provide power for operations of the electronic device 1000. The display device 1060 may be connected to other components through buses or other communication links.

The display devices (e.g., the display device DD) of embodiments of the present disclosure may be various types of display devices. For example, the display devices may be display devices for vehicles (e.g., landcraft, ships, and aircraft), portable communication devices, display devices for exhibition or information transmission, medical display devices, and the like.

According to embodiments of the present disclosure, the connectors CNT may be electrical connectors, the connection pins CPN or CPN′ of the connectors CNT may be electrical connection pins CPN or CPN′, and the connection pads CPD, CPD′, or CPD″ may be electrical connection pads. For example, each of the connectors CNT (e.g., the connection pins CPN or CPN′ of the connectors CNT) and the connections pads CPD, CPD′, or CPD″ may include a material that is electrically conductive, and the connectors CNT (e.g., the connection pins CPN or CPN′ of the connectors CNT) and the connections pads CPD, CPD′, or CPD″ may be connected together so that an electrical pathway is formed to and/or from one or more electronic elements EE (e.g., the elements ET, the voltage generator VG, and/or the driving controller TC) of the circuit board PCB through the connectors CNT (e.g., the connection pins CPN or CPN′ of the connectors CNT) and the connections pads CPD, CPD′, or CPD″.

Non-limiting example embodiments of the present disclosure have been described above with reference to the accompanying drawings. Although a few embodiments have been described with reference to the drawings, those skilled in the art will readily appreciate that many variations and modifications may be made therein without departing from the spirit and scope of the present disclosure.

What is claimed is:

1. A circuit board comprising:
a base substrate;
a connection pad on the base substrate, wherein an upper surface of the connection pad in a first direction comprises an inclined surface and a concave portion, the concave portion being at a central portion of the upper surface in a second direction that crosses the first direction; and
a connector on the connection pad, the connector comprising a connection pin that contacts the concave portion.

2. The circuit board of claim 1, wherein a thickness of the connection pad in the first direction decreases from an edge portion of the connection pad, in the second direction, to the central portion of the connection pad.

3. The circuit board of claim 2, wherein the connection pin is spaced apart from the edge portion of the connection pad.

4. The circuit board of claim 2, wherein the inclined surface of the connection pad is a concave surface, the concave surface comprising an inclination angle with respect to one surface of the base substrate, and the inclination angle increases from the central portion to the edge portion of the connection pad.

5. The circuit board of claim 2, wherein the inclined surface of the connection pad is a convex surface, the convex surface comprising an inclination angle with respect to one surface of the base substrate, and the inclination angle decreases from the central portion to the edge portion of the connection pad.

6. The circuit board of claim 1, wherein a thickness, in the first direction, of the central portion of the connection pin is greater than a thickness, in the first direction, of an edge portion of the connection pin in the second direction.

7. The circuit board of claim 1, wherein the connection pin comprises a protruding portion that protrudes toward the concave portion and contacts the concave portion.

8. The circuit board of claim 7, wherein the protruding portion comprises a triangular cross-sectional shape.

9. The circuit board of claim 7, wherein the protruding portion comprises a curvature in a cross-section.

10. The circuit board of claim 1, wherein a width of the connection pin in the second direction is smaller than a width of the connection pad in the second direction.

11. An electronic device comprising:
a display panel comprising a pixel;
a circuit board connected to the display panel;
a driving controller configured to control driving of the display panel; and
a processor configured to output an input image data and an input control signal to the driving controller,
wherein the circuit board comprises:
a base substrate;
a connection pad on the base substrate, wherein an upper surface of the connection pad in a first direction comprises an inclined surface and a concave portion, the concave portion being at a central portion of the upper surface in a second direction that crosses the first direction; and
a connector on the connection pad, the connector comprising a connection pin that contacts the concave portion.

12. The electronic device of claim 11, wherein a thickness of the connection pad in the first direction decreases from an edge portion of the connection pad, in the second direction, to the central portion of the connection pad.

13. The electronic device of claim 12, wherein the connection pin is spaced apart from the edge portion of the connection pad.

14. The electronic device of claim 11, wherein a thickness, in the first direction, of the central portion of the connection pin is greater than a thickness, in the first direction, of an edge portion of the connection pin in the second direction.

15. The electronic device of claim 11, wherein the connection pin comprises a protruding portion that protrudes toward the concave portion and contacts the concave portion.

16. The electronic device of claim 15, wherein the protruding portion comprises a triangular cross-sectional shape.

17. The electronic device of claim 15, wherein the protruding portion comprises a curvature in a cross-section.

18. A method comprising:
providing a connector on a connection pad, wherein an upper surface of the connection pad in a first direction includes an inclined surface and a concave portion, the concave portion being at a central portion of the upper surface in a second direction that crosses the first direction, and the connector includes a connection pin,
wherein the providing comprises contacting the connection pin to the concave portion of the connection pad.

19. The method of claim 18, further comprising inspecting an electrical characteristic of the connection pin while the connector is on the connection pad.

20. The method of claim 19, wherein the inspecting comprises:
contacting an inspection pin of an inspection jig to the connection pin; and
inspecting the electrical characteristic of the connection pin through the inspection pin.
